(19) United States
(12) Patent Application Publication
(10) Pub. No.: US 2025/0343195 A1
(43) Pub. Date: Nov. 6, 2025

(54) Semiconductor Devices and Methods of Making and Using Solder Bumps on FO-WLP

(71) Applicant: STATS ChipPAC Pte. Ltd., Singapore (SG)

(72) Inventors: Linda Pei Ee Chua, Singapore (SG); Rowena Zarate, Singapore (SG); Kai Chong Chan, Singapore (SG); Jian Zuo, Singapore (SG); Marites Roque, Singapore (SG); Eric Yi Jing Chong, Singapore (SG)

(73) Assignee: STATS ChipPAC Pte. Ltd., Singapore (SG)

(21) Appl. No.: 18/656,286

(22) Filed: May 6, 2024

(51) Int. Cl. H01L 23/00; H01L 21/56; H01L 23/31

(52) U.S. Cl. CPC H01L 24/20; H01L 24/19; H01L 21/561; H01L 21/568; H01L 23/3135; H01L 24/96; H01L 2224/19; H01L 2224/2105; H01L 2224/211; H01L 2224/96

(57) ABSTRACT

A semiconductor device has a semiconductor die and an encapsulant deposited over the semiconductor die. An interconnect structure is formed over the semiconductor die and encapsulant. A first under-bump metallization (UBM) pad is formed over the interconnect structure. The first UBM pad is non-circular. A stencil is disposed over the first UBM pad. The stencil includes a first opening over the first UBM pad with a footprint of the first opening larger than a footprint of the first UBM pad. A solder paste is deposited in the first opening. The solder paste is reflowed to form a solder bump on the UBM pad.

### FIELD OF THE INVENTION

The present invention relates in general to semiconductor devices and, more particularly, to semiconductor devices and methods of making and using solder bumps with fan-out wafer-level packages (FO-WLP).

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, power conversion, photo-electric, and creating visual images for television displays. Semiconductor devices are found in the fields of communications, networks, computers, entertainment, and consumer products. Semiconductor devices are also found in military applications, aviation, automotive, industrial controllers, and office equipment.

Fan-out wafer-level packages (FO-WLP) are a common package topology for semiconductor manufacturing today. FO-WLP devices typically have under-bump metallization (UBM) pads formed over them. Solder is printed onto the UBM pads using a stencil. A solder paste is disposed into stencil openings on the UBM pads and then reflowed to form a solder bump.

A common issue with stencil printing of solder paste is that the solder paste may be deposited into the stencil openings with voids. The solder paste voids result in inconsistent bump height due to insufficient solder volume coverage, as well as irregularly shaped bumps that do not completely cover their respective UBM pads. These concerns are most prevalent with non-circular UBM pads. Rectangular or oblong UBM pads will commonly have trouble with their peripheries or ends not being completely covered in solder after bump reflow. Additionally, within groups of pads on a FO-WLP, the greatest concern is with the outermost pads at the edges of groupings. Therefore, a need exists for improved bumping devices and methods for FO-WLP devices.

### BRIEF DESCRIPTION OF THE DRAWINGS

FIGS. 1a-1c illustrate a semiconductor wafer with a plurality of semiconductor die separated by a saw street;

FIGS. 2a-2j illustrate a process of forming a fan-out wafer-level package;

FIGS. 3a-3h illustrate stencil openings having larger footprints relative to an underlying under-bump metallization pads;

FIGS. 4a-4h illustrate stencil openings for rectangular UBM pads;

FIGS. 5a-5d illustrate different stencil opening sizes used for different situations; and

FIGS. 6a and 6b illustrate integrating the fan-out wafer-level packages into an electronic device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the semiconductor package. The electrical connections can be made with conductive layers, bumps, stud bumps, conductive paste, or wirebonds. An encapsulant or other molding material is deposited over the semiconductor package to provide physical support and electrical isolation. The finished semiconductor package is then inserted into an electrical system and the functionality of the semiconductor device is made available to the other system components.

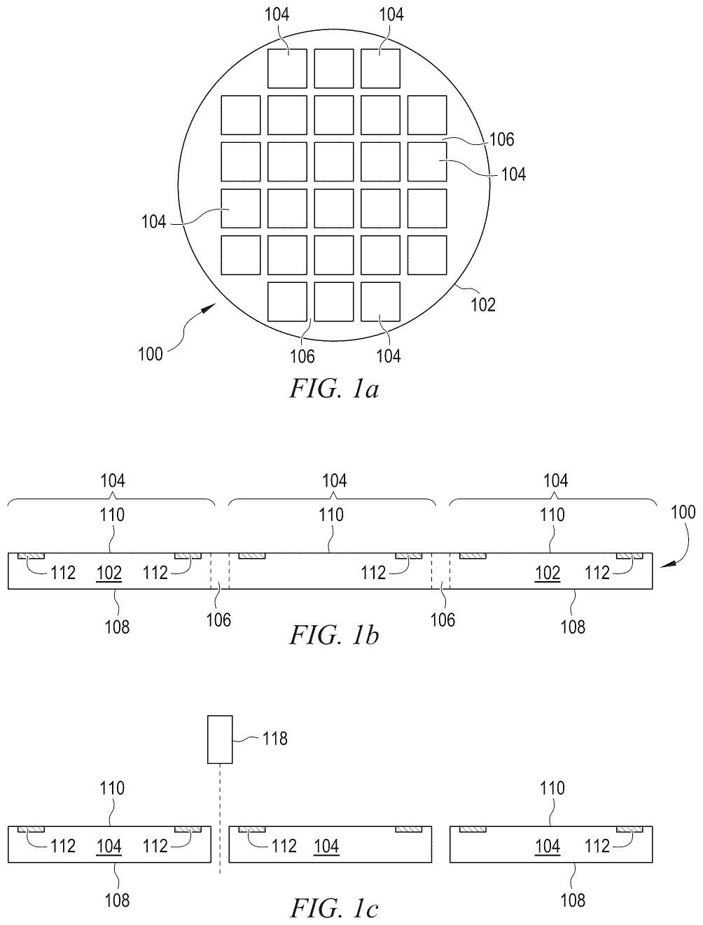

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuit (ASIC), memory, power device, or other signal processing circuit. Semiconductor die 104 may also contain integrated passive devices (IPDs), such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Any conductive layer mentioned below can be formed using any of the materials or methods described for conductive layer 112.

Conductive layer 112 operates as contact pads electrically connected to the circuits on active surface 110. Incoming wafer 100 is backgrinded to reduce a thickness of the wafer before singulation and packaging.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

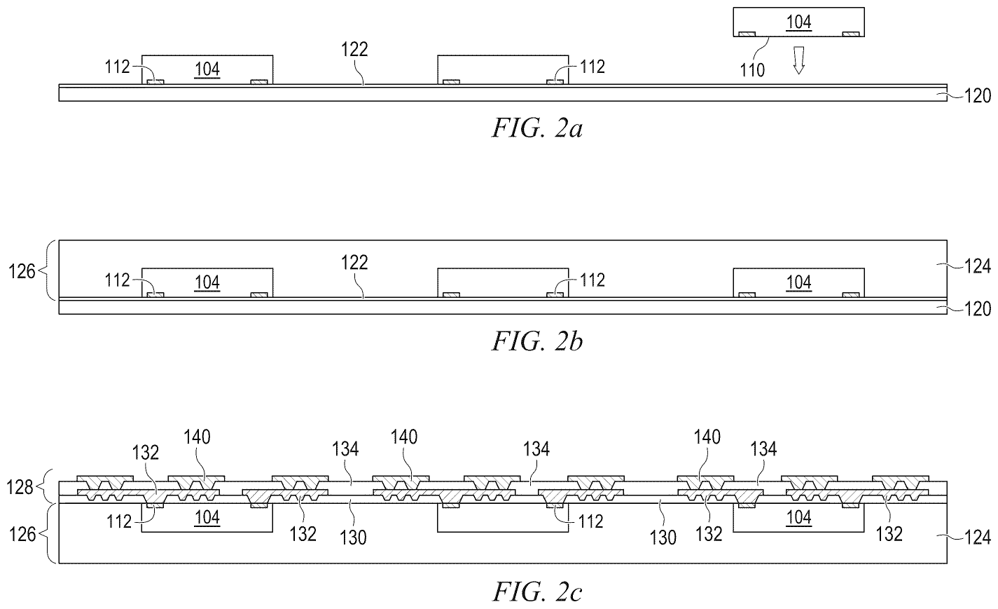

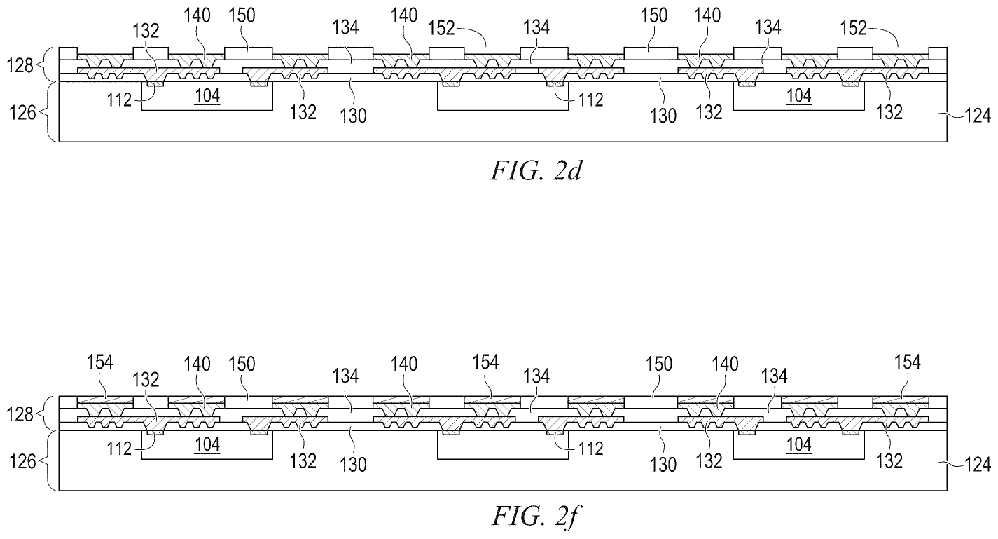

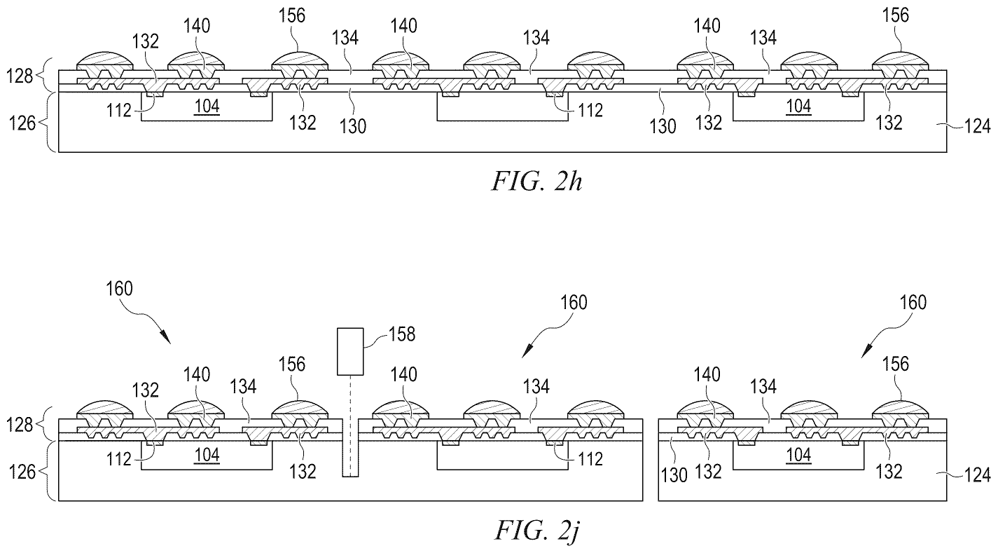

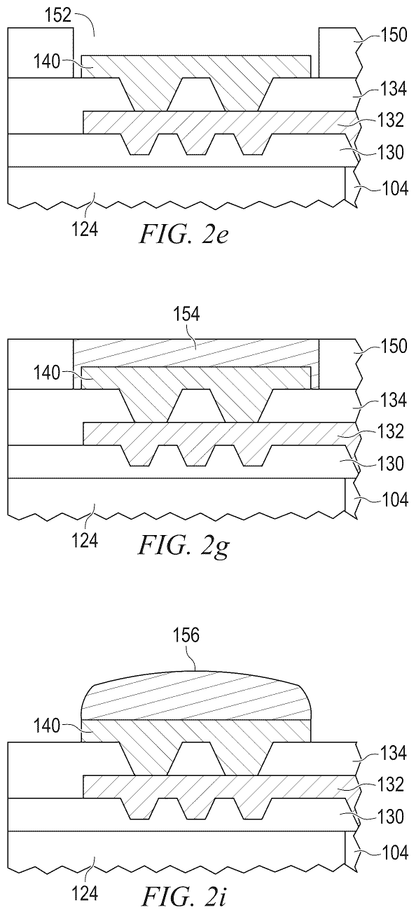

FIGS. 2a-2j illustrate a process of forming fan-out wafer-level semiconductor packages (FO-WLP). In FIG. 2a, a plurality of semiconductor die 104 are picked and placed onto a carrier 120 containing sacrificial base material such as silicon, polymer, beryllium oxide, glass, or other suitable low-cost, rigid material for structural support. An interface layer or double-sided tape 122 is formed or disposed over carrier 120 as a temporary bonding film, thermal release layer, or UV release layer. To simplify illustration, the packages being formed each includes a single semiconductor die 104 and no other components. In other embodiments, much more complicated packages can be formed with multiple semiconductor die, additional discrete active or passive components, or any other desired electrical components. While carrier 120 is illustrated as large enough for manufacturing three devices together, a typical carrier can handle hundreds or thousands of devices at once. Semiconductor die 104 are disposed with active surfaces 110 oriented toward carrier 120.

In FIG. 2b, encapsulant or molding compound 124 is deposited over and around semiconductor die 104 using a paste printing, compressive molding, transfer molding, liquid encapsulant molding, vacuum lamination, spin coating, or other suitable applicator. Encapsulant 124 can be liquid or granular polymer composite material, such as epoxy resin, epoxy acrylate, or another suitable polymer, with or without a suitable filler. Encapsulant 124 is non-conductive, provides structural support, and environmentally protects the semiconductor device from external elements and contaminants. Semiconductor die 104 are disposed with active surfaces 110 oriented toward carrier 120, so that, once the carrier is removed, the active surfaces are exposed from encapsulant 124 for subsequent electrical connection to contact pads 112. Encapsulant 124 undergoes a post-mold cure (PMC) process.

The combination of semiconductor die 104 and encapsulant 124 forms a reconstituted wafer 126. The term reconstituted wafer indicates that reconstituted wafer 126 can be analogized to semiconductor wafer 100 from which semiconductor die 104 were singulated in FIG. 1c. In a sense, semiconductor wafer 100 has been reconstituted with semiconductor die 104 further spread out to facilitate the formation of fan-out interconnect structures over active surfaces 110 after deposition.

FIG. 2c illustrates carrier 120 removed or debonded by mechanical peeling, thermal release, UV release, or another suitable means. Reconstituted wafer 126 is flipped so that active surfaces 110 are oriented upward. An automated optical inspection process is optionally performed on the surface of reconstituted wafer 126 with active surfaces 110 exposed after removing carrier 120 before a fan-out build-up interconnect structure 128 is formed over reconstituted wafer 126.

Interconnect structure 128 is a fan-out interconnect structure, indicating that the ultimate electrical connections being formed at the top of the interconnect structure cover a wider footprint than those of contact pads 112 at the bottom of the interconnect structure. Interconnect structure 128 being called a build-up interconnect structure refers to the way that the interconnect structure is formed by successively building up insulating layers and conductive layers over reconstituted wafer 126 until the desired signal routing is achieved.

Forming interconnect structure 128 starts by forming insulating or passivation layer 130 on reconstituted wafer 126. Passivation layer 130 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI) benzocyclobutene (BCB), polybenzoxazoles (PBO), and other material having similar insulating and structural properties. Passivation layer 130 can be formed using PVD, CVD, printing, lamination, spin coating, spray coating, sintering, or thermal oxidation. Any insulating, passivation, or dielectric layer mentioned above or below can be formed using any of the materials or methods described for passivation layer 130.

Openings are formed through passivation layer 130 to expose contact pads 112. The openings can be formed by chemical etching, photolithography, mechanical drilling, laser drilling, or any other suitable means. A conductive layer 132 is formed over passivation layer 130, including through openings of the passivation layer to physically and electrically couple to contact pads 112. Conductive layer 132 is formed of any of the materials and using any of the methods described above for contact pads 112. Conductive layer 132 is etched or selectively formed to include conductive traces fanning out from contact pads 112. Conductive layer 132 also includes contact pads for subsequently formed conductive layers to connect to.

In some embodiments, vias are formed into or through passivation layer 130 under the contact pads of conductive layer 132 so that the contact pads include portions extending downward toward reconstituted wafer 126. The protrusions can be a plurality of vias formed as points, concentric circles, or any other desired shape. The protrusions under conductive layer 132 reduce warpage during manufacturing and improve adhesion of conductive layer 132 to passivation layer 130. Any desired number of insulating layers and conductive layers can be interleaved on top of each other as desired to implement the desired signal routing. More layers allow more complex signal routing while also complicating the manufacturing process.

An insulating layer 134 is formed over passivation layer 130 and conductive layer 132. Insulating layer 134 is formed using any of the processes and materials described above for passivation layer 130. Openings are formed through insulating layer 134, as with insulating layer 130, to expose contact pads of conductive layer 132. In some embodiments, multiple openings are formed per contact pad, or one or more circular openings are formed, providing a discontinuous opening for each contact pad in some cross-sections. In other embodiments, one large opening is formed per contact pad. The top surface of insulating layer 134 with openings exposing conductive layer 132 optionally undergoes an automated optical inspection process prior to proceeding further.

Contact pads or under-bump metallization (UBM) pads 140 are formed over insulating layer 134 and through the openings to physically and electrically couple to the contact pads of underlying conductive layer 132. UBM pads 140 are formed using any of the materials and methods described above for contact pads 112. In some embodiments, UBM pads 140 are formed with a wetting layer, a barrier layer, and an adhesion layer. UBM pads 140 can be any desired size and shape and formed into any desired distribution pattern across the top surface of interconnect structure 128. An optional automated optical inspect process is performed at this stage to inspect UBM pads 140.

FIG. 2d shows the beginning of the bumping process, which uses a stencil 150 disposed over interconnect structure 128. Stencil 150 is a sheet of polymer, metal, or other material formed by rolling, molding, slicing, or another suitable method. Stencil 150 includes openings 152 over each UBM pad 140 on which a solder bump is to be formed. Openings 152 are formed by mechanical drilling, laser etching, chemical etching, molding, or another suitable process.

FIG. 2e shows a close-up view of a UBM pad 140, demonstrating that stencil opening 152 is larger than the UBM pad in at least one cross-section. Stencil opening 152 in FIG. 2e has a larger dimension in the illustrated cross-section than UBM pad 140, which could be the length, width, diagonal, or any other direction. In some embodiments, opening 152 extends outside the footprint of UBM pad 140 in only one direction, i.e., only left or only right in the illustrated cross-section. The greater dimension of stencil opening 152 results in a gap between the outer side surface of UBM pad 140 and the inner side surface of stencil 150 in stencil opening 152.

Openings 152 allow the deposition of solder paste 154 onto UBM pads 140 as shown in FIG. 2f. In one embodiment, solder paste 154 is disposed excessively over each opening 152 or over the entire stencil 150, and then a squeegee or other type of blade slides across the stencil to press the solder paste into the openings and remove excess solder paste.

FIG. 2g is a close-up view of a UBM pad 140 showing solder paste 154 fills opening 152 and extends outside a footprint of UBM pad 140. Solder paste 154 may or may not extend down into or completely fill the lateral gap between UBM pad 140 and stencil 150. Openings 152 are formed slightly larger than a corresponding UBM pad 140 in at least one direction to increase the amount of solder paste 154 that can be deposited into the opening. Slightly larger openings 152, relative to corresponding UBM pads 140, reduce the likelihood that solder paste 154 will have voids and also reduces the negative consequences of voids that remain by allowing additional solder to make up for any voids.

In FIG. 2h, stencil 150 is removed, and solder paste 154 is reflowed by heating above its melting temperature to form solder bumps 156. FIG. 2i shows a closer view of a UBM pad 140. The portion of solder paste 154 that was deposited outside the footprint of UBM pad 140 is pulled in by the surface tension of the melted solder to create a solder bump 156 that is formed only on the top surface of the UBM pad. UBM pad 140 can have a wetting layer on only the top surface to facilitate solder paste 154 forming a bump 156 on only the top surface of the UBM pad.

An optional automated optical inspect process is performed at this stage to inspect solder bumps 156. Because stencil 150 had openings 152 that were larger than corresponding UBM pads 140 in at least one direction, solder bumps 156 are reliably formed with a consistent height over the UBM pads and fully covering all of the UBM pads. Semiconductor packages are completed by optionally taping reconstituted wafer 126 and backgrinding encapsulant 124 to reduce a thickness of the packages, laser marking the encapsulant, detaping, and then mounting the reconstituted wafer for singulation.

Reconstituted wafer 126 is singulated using a saw blade or laser cutting tool 158 in FIG. 2j to separate the reconstituted wafer into individual FO-WLP 160. After singulation, FO-WLP 160 can be picked and placed into a tape-and-reel or other container for storage and shipping or mounted directly onto a PCB or substrate of a larger electronic device.

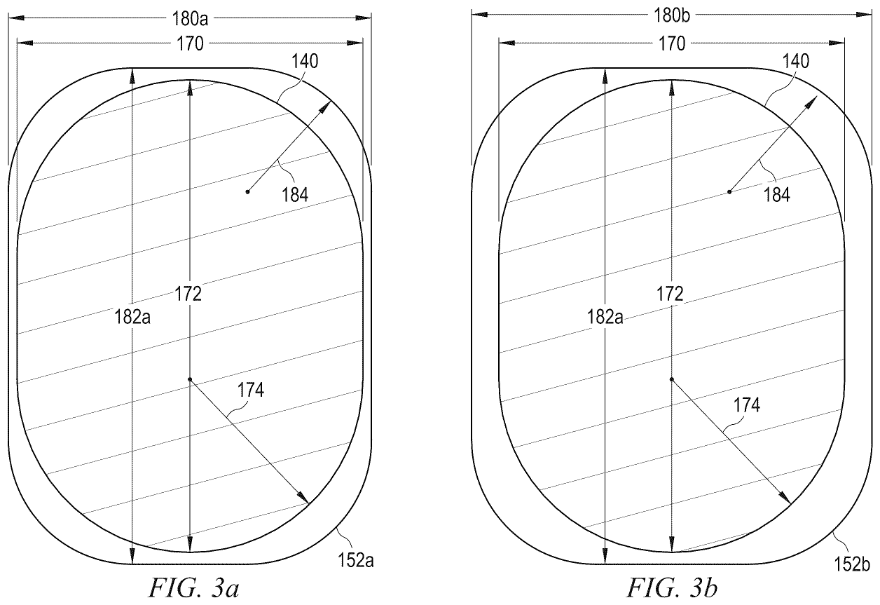

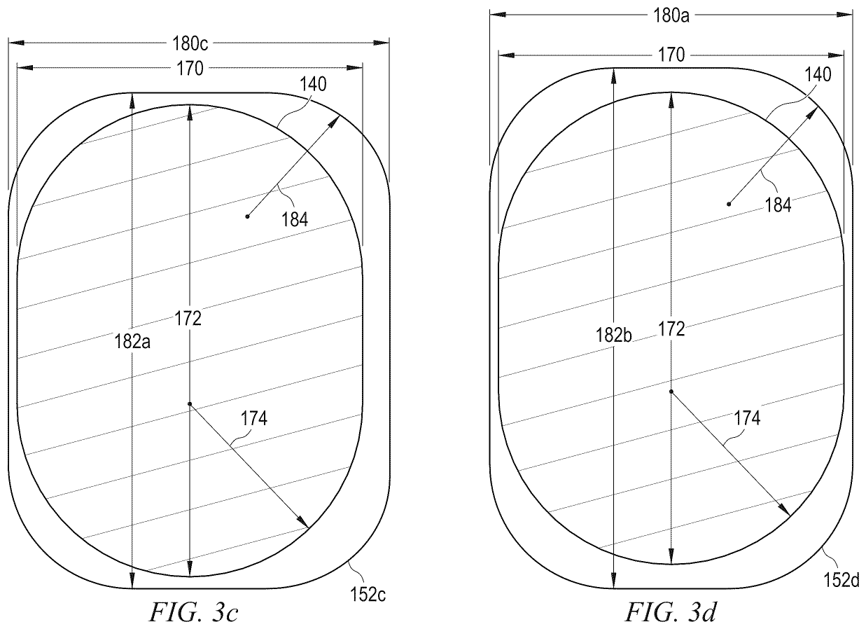

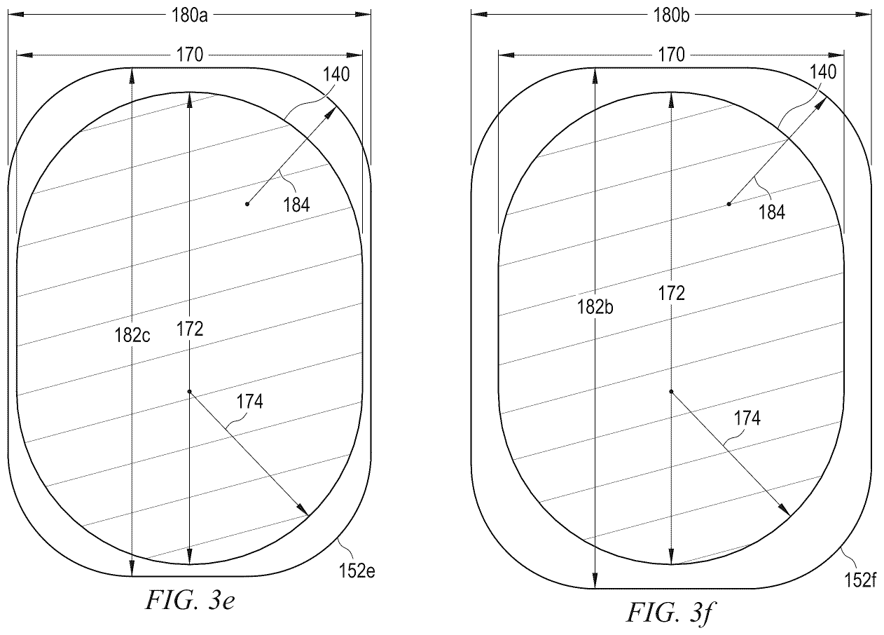

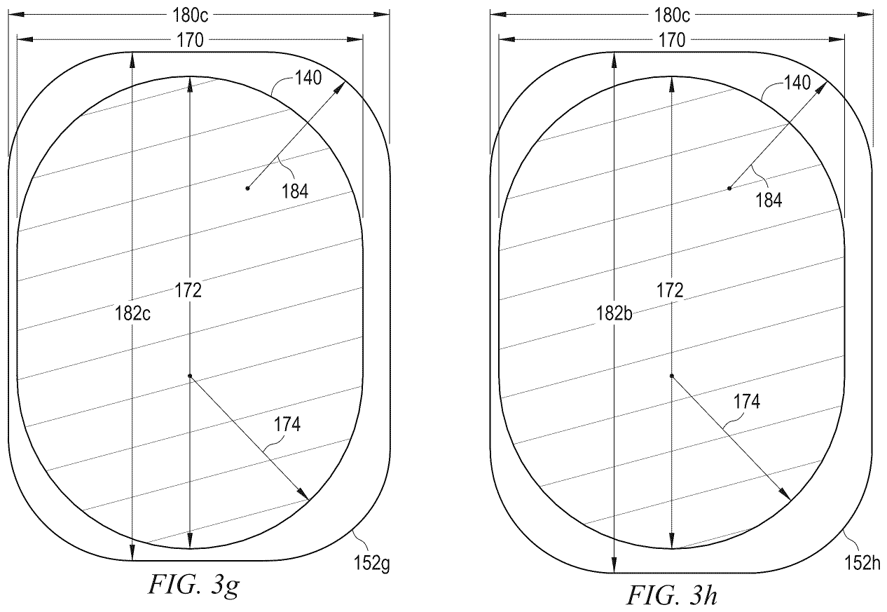

FIGS. 3a-3h illustrate additional details of UBM pads 140 and stencil openings 152 in a variety of configurations. FIGS. 3a-3h show plan views of a UBM pad 140 and stencil openings 152 over the UBM pad with various stencil opening sizes. UBM pad 140 has the same size in each example while the stencil opening 152 size varies depending on the position of the particular UBM pad 140 relative to other UBM pads. UBM pad 140 is oblong shaped with a width illustrated by line 170 and a length illustrated by line 172. Being oblong shaped means that UBM pad 140 has two half-circular ends with two linear sides connecting the two half circles, thus extending the length 172 to be greater than the width 170. UBM pad 140 may also be an oval, rectangle, or other elongated shape. In one embodiment, UBM pad 140 has a width of 290 micrometers (μm) and a length of 396 μm.

The ends of UBM pad 140 are circular with a radius indicated by arrow 174. Arrow 174 starts at a point centered along width 170 because the radius is half of width 170. In other embodiments, UBM pad 140 can be formed with a corner radius less than or greater than half of width 170. In the example dimensions given in the previous paragraph, the corner radius would be 145 μm, half of width 170, thus resulting in a half circle at each end of UBM pad 140.

Stencil opening 152 is formed with a length and width greater than the corresponding dimensions of UBM pad 140. FIG. 3a shows a UBM pad 140 with a stencil opening 152a. Stencil opening 152a includes a width 180a greater than width 170 of UBM pad 140 and a length 182a greater than length 172 of the UBM pad. Having larger dimensions increases the amount of solder paste 154 that is deposited and thereby creates bumps 156 of a more consistent size and shape.

Opening 152a is a good default size for stencil opening 152, which can then be customized for each UBM pad 140 depending on the specific position of each UBM pad. In one embodiment, stencil opening 152a has a width 180a of 300 μm, a length 182a of 400 μm, and a corner radius of 100 μm. The default size of opening 152a is limited by the minimum gap between immediately adjacent stencil openings 152. In one embodiment, a width of stencil 150 between adjacent stencil openings 152 needs to be maintained to at least 50 μm, and a gap between immediately adjacent UBM pads 140 in the width direction is 70 μm. Therefore, immediately adjacent stencil openings 152 can be grown toward each other by 10 μm each and still maintain a 50 μm width of stencil 150 between the openings.

Having a smaller corner radius than UBM pad 140 means that, even with the same length and width, stencil opening 152 will be longer in a diagonal direction than the UBM pad. In some embodiment, simply having corners of stencil opening 152 extending outside the footprint of UBM pad 140, even with identical lengths and widths, increases the amount of solder paste 154 deposited sufficiently to overcome problems with solder paste voids.

FIG. 3b shows a stencil opening 152b disposed over another UBM pad 140. Stencil opening 152b has the same length 182a as stencil opening 152a, but has been elongated in the width direction, with a width 180b wider than width 180a. Width 180b is between 312 μm and 320 μm, inclusively, in one embodiment. Width 180b is specifically either 312 μm or 320 μm in another embodiment. Opening 152b is for UBM pads 140 that have immediately adjacent UBM pads on both top and bottom, but no immediately adjacent UBM pad to the left or to the right, e.g., a pad within a string of pads that follow a linear path vertically. Therefore, opening 152b can be expanded both left and right relative to opening 152a but is not expandable either up or down.

FIG. 3c shows a stencil opening 152c that is expanded only to the right and not to the left. Stencil opening 152c is usable with UBM pads 140 formed along a right edge of a group of pads, with immediately adjacent UBM pads to the top, left, and bottom. Therefore, opening 152c is only expandable to the right. Opening 152c has a width 180c greater than width 180a but less than width 180b. Width 180c is between 305 μm and 310 μm, inclusively, in one embodiment. Width 180c is specifically either 305 μm or 310 μm in another embodiment. Opening 152c still has the same length 182a as openings 152a and 152b.

FIG. 3d shows a stencil opening 152d disposed over another UBM pad 140. Stencil opening 152d has the same width 180a as stencil opening 152a, but has been elongated in the length direction, with a length 182b greater than length 182a. Length 182b is between 412 μm and 420 μm, inclusively, in one embodiment. Length 182b is specifically either 412 μm or 420 μm in another embodiment.

Opening 152d is for UBM pads 140 that have immediately adjacent UBM pads on the left and right, but no immediately adjacent UBM pad to above or below, e.g., a pad within a string of pads that follow a linear path horizontally. Therefore, opening 152d can be expanded both up and down relative to opening 152a but is not expandable either left or right.

FIG. 3e shows a stencil opening 152e that is expanded only upward and not downward. Stencil opening 152e is usable with UBM pads 140 formed along a top edge of a group of pads, with immediately adjacent UBM pads to the left, bottom, and right. Therefore, opening 152e is only expandable upward. Opening 152e has a length 182c greater than length 182a but less than length 182b. Length 182c is between 405 μm and 410 μm, inclusively, in one embodiment. Length 182c is specifically either 405 μm or 410 μm in another embodiment. Opening 152e still has the same width 180a as opening 152a.

FIG. 3f shows a stencil opening 152f disposed over another UBM pad 140. Stencil opening 152f has both an elongated length 182b and an elongated width 180b relative to stencil opening 152a. Opening 152f can be used with isolated UBM pads 140 that do not have an immediately adjacent UBM pad in any direction and are therefore not limited insofar as available directions for expansion.

FIG. 3g shows an opening 152g that is expanded both up and right, but neither down nor left. Opening 152g can be used with UBM pads 140 at a corner of a group of pads, with an immediately adjacent UBM pad in two non-opposite directions. Opening 152g has width 180c and length 182c.

FIG. 3h shows a stencil opening 152h formed over UBM pad 140. Stencil opening 152h is expanded in three directions and is usable at the end of a line of pads where the end UBM pad is only immediately adjacent to one other pad. Opening 152h is expanded in only a single direction in the width dimension but both directions in the height dimension, i.e., expanded up, down, and right but not left. Opening 152h has a length 182b and width 180c. A similar pad opening could be formed by expanding in three directions left, right, and up and have a length 182c and width 180b.

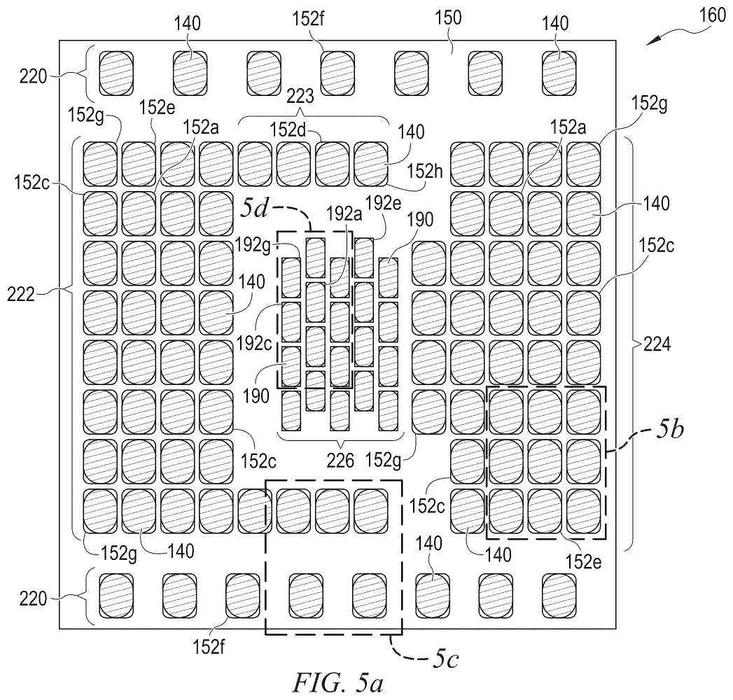

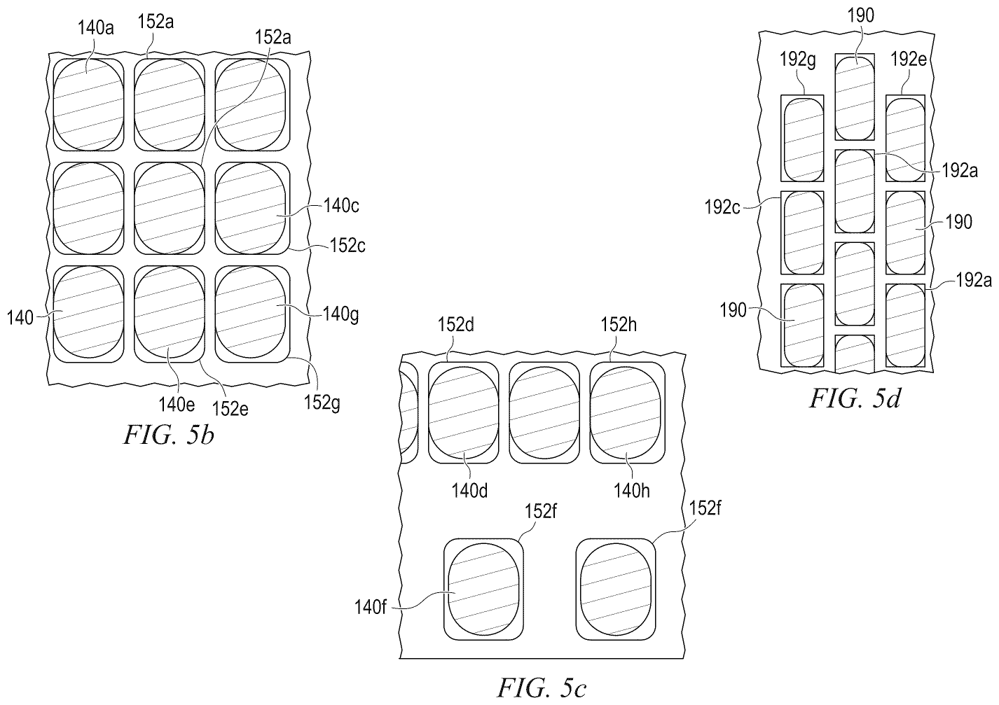

Each stencil opening 152a-152h includes the same corner radius 184 of 100 μm, while simply elongating the length, width, or both, in either one direction or both. In other embodiments, the corner radius 184 can also be customized to fine tune the overall area of the openings. In some situations, two stencil openings can have different lengths or widths, but a common footprint area can be maintained by changing the corner radius to compensate. Additional specific situations when openings 152a-152h are used will be explained below with reference to FIGS. 5a-5d.

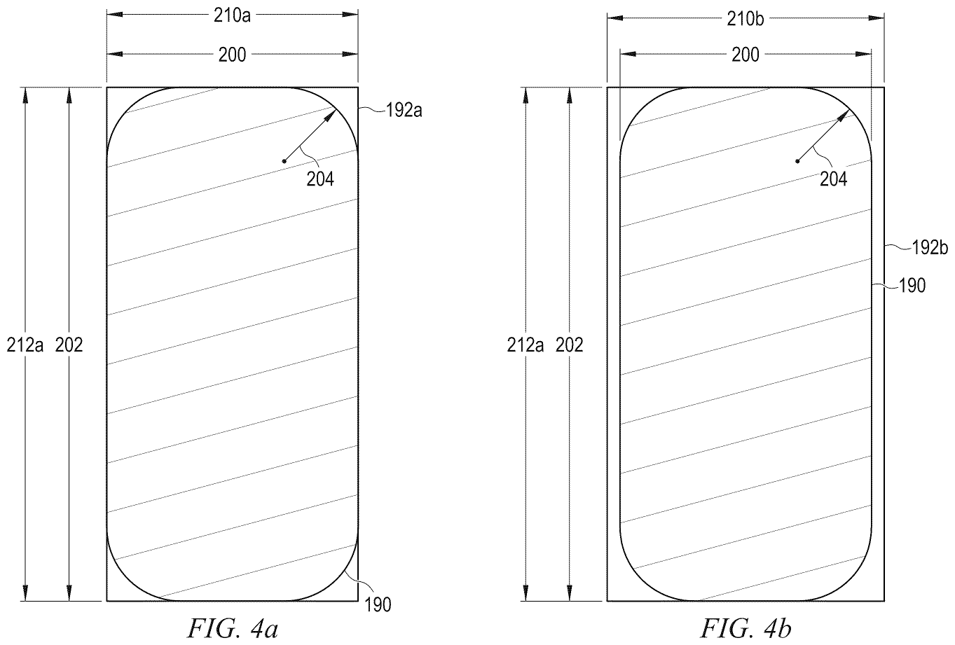

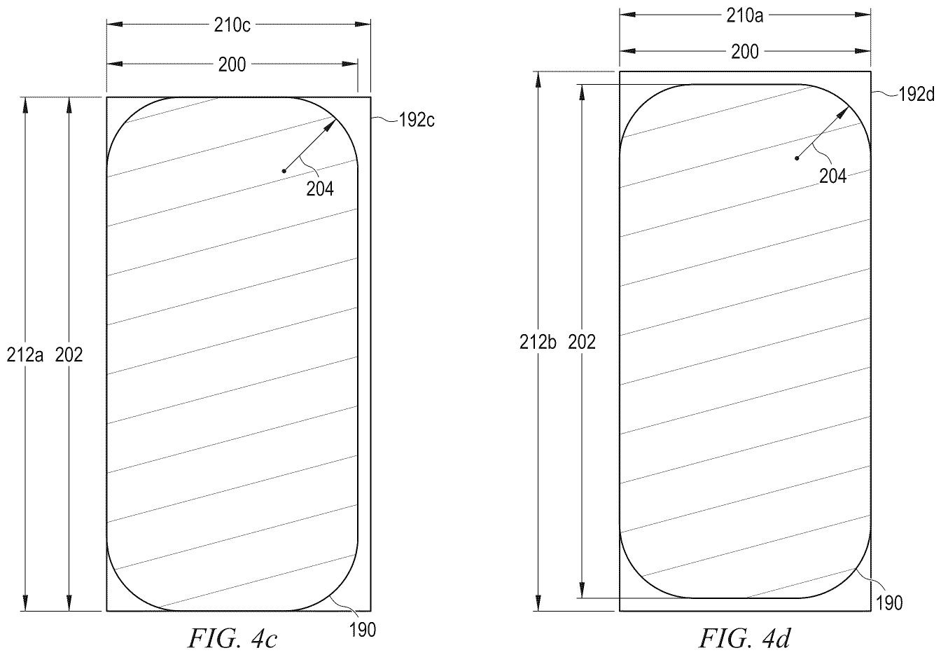

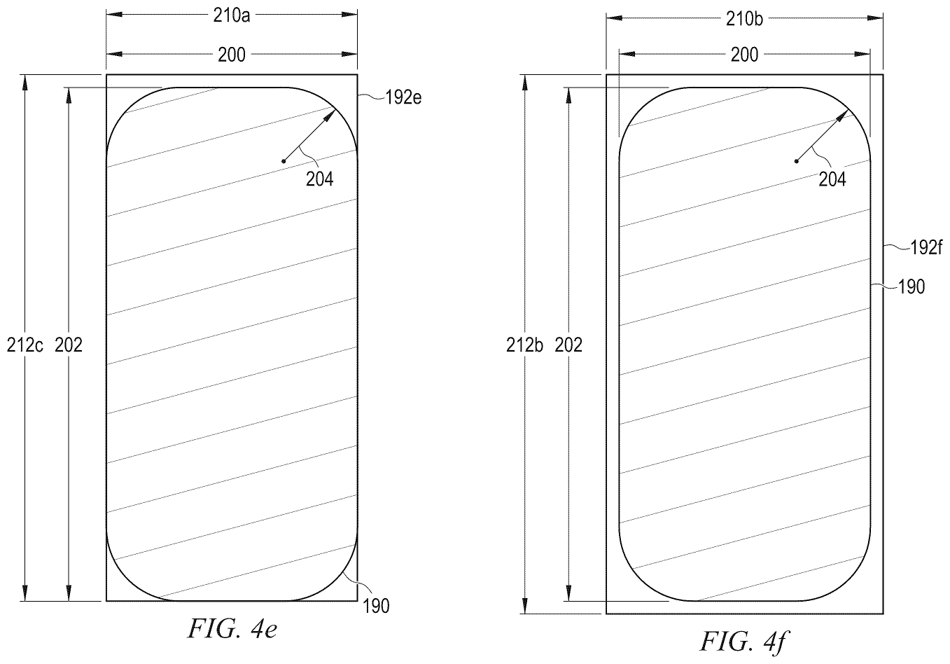

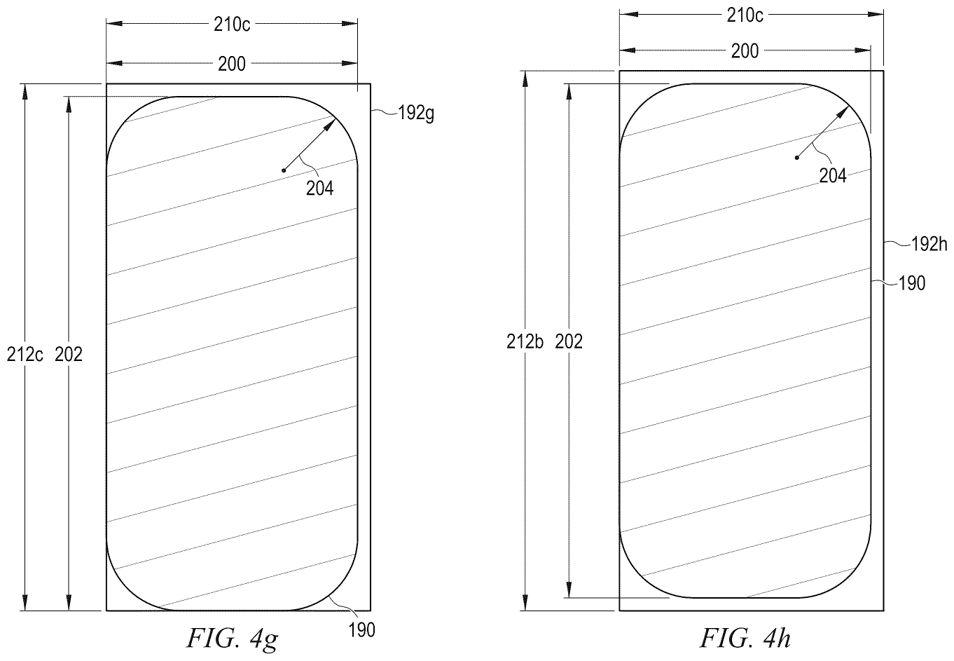

FIGS. 4a-4h illustrate a similar concept to FIGS. 3a-3h, but with a rectangular UBM pad 190 instead of the oblong UBM pad 140. UBM pad 190 is described as being rectangular because the UBM pad includes four linear sides connected at perpendicular angles defining a width 200 and a length 202. The corners of UBM pad 190 are radiused as with UBM pad 140, but radius 204 is less than half of width 200 to give UBM pad 190 a rectangular shape. In one embodiment, UBM pad 190 has a length 202 of 353 μm, a width 200 of 172 μm, and a corner radius 204 of 50 μm. UBM pad 190 can be used in combination with UBM pad 140 on the same FO-WLP device.

FIG. 4a shows a stencil opening 192a over a UBM pad 190. Stencil opening 192a has a width 210a identical to width 200 and a length 212a identical to length 202. Stencil opening 192a is a rectangle without radiused corners, i.e., a corner radius of zero. In other embodiments, stencil opening 192a has a corner radius greater than zero and less than radius 204 so that the stencil opening still extends outside a footprint of UBM pad 190. Opening 192a does not have a greater length or a greater width than UBM pad 190 because UBM pads 190 are typically closer together than pads 140 and do not have room to expand between immediately adjacent pads without breaking the 50 μm separation rule. In other embodiments, especially where the distance between pads is greater than the required minimum stencil width, rectangular pads can have some expansion by default.

FIG. 4b shows a stencil opening 192b with an elongated width 210b, elongated both left and right, but the same length 212a as stencil opening 192a. Stencil openings 192b are used with pads 190 that have immediately adjacent pads 190 both up and down, but no adjacent pad to the left or to the right. In one embodiment, width 210b is 182 μm. Other widths are used in other embodiments. Stencil opening 192b still has a corner radius of zero but could have a greater corner radius.

FIG. 4c shows an opening 192c with width 210c expanded only to the right relative to opening 192a. Opening 192c is used when a pad is on the right edge of a group of pads with immediately adjacent pads above, below, and to the left. In one embodiment, width 210c is 177 μm.

FIG. 4d shows a stencil opening 192d with a length 212b expanded both up and down but the same width 210a as stencil opening 192a. Stencil openings 192d are used for UBM pads 190 when the UBM pad has immediately adjacent pads to the left and right but neither up nor down. In one embodiment, length 212b is 363 μm. Other lengths are used in other embodiments. Stencil opening 192c still has a corner radius of zero but could have a greater corner radius.

FIG. 4e shows an opening 192e with length 212c grown only upward relative to opening 192a. Opening 192e is used when a pad is on the top edge of a group of pads with immediately adjacent pads to the left, right, and downward. In one embodiment, length 210c is 358 μm.

FIG. 4f shows a stencil opening 192f with an elongated width 210b and an elongated length 212b. Stencil opening 192f still has a corner radius of zero but could have a greater corner radius. Opening 192f is usable with pads 190 that are isolated without an immediately adjacent UBM pad in any direction.

FIG. 4g shows a stencil opening 192g with an elongated width 210c and length 212c. Stencil opening 192g is elongated up and right, but not down or left, compared to opening 192a. Opening 192g is usable with pads 190 that are on corners of groups, having immediately adjacent UBM pads in exactly two non-perpendicular directions.

FIG. 4h shows a stencil opening 192h with an elongated width 210c and length 212b. Stencil opening 192h is elongated up, down, and right compared to stencil opening 192a. Stencil opening 192h is usable in situations where UBM pad 190 has one immediately adjacent pad to the left. A similar stencil opening could be formed with width 210b and length 212c.

The general rule for any pad, including UBM pads 140 and 190, is that the stencil openings should be expanded as far as possible within a group of pads while maintaining the minimum stencil width, e.g., 50 μm in the above examples. Furthermore, pads that are not within the middle of a group of pads can be further expanded in any direction where there is no other immediately adjacent pad. Having stencil openings 192 with a larger footprint than a corresponding UBM pad 190 reduces the amount of solder paste voids, as well as the impact of the solder paste voids that remain.

The same concepts illustrated with regard to UBM pads 140 and 190 will also work with any size and shape of UBM pad. A reduced corner radius, increased length, increased width, any combination of the three, or any other method of increasing footprint size of a stencil opening relative to a contact pad or UBM pad can be used in various embodiments. Bumps are formed on UBM pad 190 as illustrated in FIGS. 3e-3g.

FIGS. 5a-5d illustrate one specific embodiment with various groupings of UBM pads 140 and 190 on FO-WLP 160 to demonstrate how the various sizes of stencil openings can be used. While directional words such as horizontal, vertical, above, below, top, bottom, left, and right are used herein to refer to the relative positions and orientations of UBM pads 140 and 190, directional words are only used to describe relative position within the specific angles and views illustrated in FIGS. 3a-3h, 4a-4h, and 5a-5d, and not meant to be taken out of the context of those figures.

FO-WLP 160 in FIG. 5a includes several groupings of UBM pads 140 and 190. Two lines 220 of UBM pads 140 are formed at the top and bottom of the FO-WLP 160 footprint. Lines 220 each includes either seven or eight UBM pads 140 spread out across the entire width of FO-WLP 160. UBM pads 140 in line 220 are relatively spread out and the corresponding stencil openings 152 could be expanded in any direction to any reasonable size. UBM pads 140 are not really a group of UBM pads, but rather a plurality of individual UBM pads.

A group 222 of UBM pads 140 is formed on the left side of FO-WLP 160 in FIG. 5a. Group 222 is a rectangle of UBM pads 140 with two arms 223 extending toward the right side of FO-WLP 160 at the top and bottom of the group. Another group 224 of UBM pads 140 is formed on the right side of FO-WLP 160 in FIG. 5a. Group 224 is rectangular with an additional shorter column of UBM pads 140 formed along the left-hand edge of the group. A rectangular group 226 of UBM pads 190 is formed centrally in the middle of FO-WLP 160. Group 226 consists of five columns of UBM pads 190 with each column being vertically offset from adjacent columns.

UBM pads 140 and 190 in FIG. 5a utilize various stencil opening sizes depending on where the UBM pads fall within the groups. UBM pads 140 and 190 are too small in FIG. 5a to actually illustrate the different sizes of stencil opening. FIGS. 5b-5d have blown up views of portions of FIG. 5a to show how the different stencil opening sizes are used. Stencil openings 152 and 192 are not necessarily drawn to scale in FIGS. 5b-5d but have exaggerated dimensions to better illustrate which stencil openings are elongated in which directions.

In general, the groups of UBM pads have stencil openings 152a and 192a that are the default sizes from FIGS. 3a and 4a within the middle of the groupings where the UBM pads are surrounded by other UBM pads on all four sides. At the edges of the groups, UBM pads have openings 152c, 152e, 192c, and 192e that are stretched in only one direction perpendicular to the edge of the group where the UBM pads are located and outward from the group. In the corners of groupings, where UBM pads have exactly two non-opposite sides without another immediately adjacent UBM pad, stencil openings 152g or 192g are used with elongation on only one side in both length and width. Stencil openings 152b, 152d, 192b, and 192d are used in lines of UBM pads, such as arms 223, where two opposing sides of a UBM pad have immediately adjacent UBM pads and the two other opposing sides have no immediately adjacent UBM pads. Openings 152f and 192f with elongation in both directions of length and width are used for UBM pads that do not have immediately adjacent UBM pads in any direction, such as those in lines 220. Openings 152h or 192h are used at the end of lines 222 and other situations where a UBM pad 150 or 190 has only one immediately adjacent UBM pad.

When UBM pads are in multiple groups, the UBM pads within the group are considered to be immediately adjacent to each other while the gaps between groups cause UBM pads from different groups to not be immediately adjacent to each other. More generally, UBM pads are considered to be immediately adjacent to each other when the spacing between two UBM pads is consistent with the spacing between UBM pads within a group of UBM pads on a given package. In some embodiments, UBM pads are only considered to be immediately adjacent to each other when the spacing between them is consistent with or approximately equal to the smallest spacing between commonly sized UBM pads on the package in a given direction, e.g., horizontally or vertically. That is, the spacing required for UBM pads to be considered immediately adjacent may be different in one direction than another if the smallest spacing between commonly sized UBM pads is different in those two directions.

FIGS. 5b-5d illustrate detailed views of FIG. 5a to apply the above-described sizing rules. FIG. 5b shows a bottom-right corner of group 224. FIG. 5b illustrates three columns and three rows from group 224, for a total of nine UBM pads 140. The four UBM pads 140a that form a square in the top-left corner of FIG. 5b each has another UBM pad 140 immediately adjacent in all four cardinal directions. Therefore, stencil openings 152a without any additional elongation in length or width are used over UBM pads 140a. The same applies to all UBM pads 140 in FIG. 5a that are located internal within the groups, i.e., those that have immediately adjacent UBM pads in all four cardinal directions.

The bottom right UBM pad 140g in FIG. 5b is in a corner of group 224 and has two immediately adjacent UBM pads, one above and one to the left. Therefore, UBM pad 140g has two non-opposite sides, bottom and right, without another immediately adjacent UBM pad, and uses a stencil opening 152g that is elongated in both length and width but only toward the directions external to group 224. All corner UBM pads 140 in groups 222 and 224 follow the same rule, including the top and bottom UBM pads in the shorter column at the far left of group 224. Because group 224 has a shorter column along the left edge, group 224 actually has six corners that follow the corner rule and use stencil opening 152g, two on the left-most column, two on the second column from the left, and two on the right-most column. Group 222 only has two such corners, on the left-most column of group 222, because arms 223 keep the top-right and bottom-right corners of group 222 from having a UBM pad 140 with immediately adjacent UBM pads on only two non-opposite sides. In one embodiment, the eight corners of groups 222 and 224 utilize stencil openings with a length of 405 μm and a width of 305 μm.

On the right and left edges of groups 222 and 224, which are edges that extend vertically in the figure, stencil openings 152c are used, which are larger than openings 152a in only the horizontal direction, perpendicular to the edge the UBM pads are on, and only in the direction external to the group. The specific UBM pads 140 being referred to as on the left and right edges are those UBM pads that have another immediately adjacent UBM pad both above and below, and only one immediately adjacent UBM pad either to the left or to the right. FIG. 5b shows the left and right edge UBM pads as UBM pads 140c. In one embodiment, the left and right edge UBM pads 140b use a stencil opening with a length of 400 μm and a width of 310 μm.

On the top and bottom edges of groups 222 and 224, which are edges that extend horizontally in the figure, stencil openings 152e are used, which are longer than openings 152a in only vertically, perpendicular to the edge the UBM pads are on, and only in the direction oriented out from the group. The specific UBM pads 140 being referred to as on the top and bottom edges are those UBM pads that have another immediately adjacent UBM pad both to the left and to the right, and only one immediately adjacent UBM pad either above or below. FIG. 5b shows the top and bottom edge UBM pads as UBM pads 140e. In one embodiment, the top and bottom edge UBM pads 140e use a stencil opening with a length of 405 μm and a width of 300 μm.

FIG. 5c shows an arm 223 and a pair of UBM pads 140 from a line 220. UBM pads 140 in the middle of an arm, i.e., those UBM pads that have immediately adjacent UBM pads on only two opposite sides, are elongated in only the direction where there are no immediately adjacent UBM pads. For the middle UBM pads 140 of arms 223, stencil openings 152d are used, elongated upward and downward compared to opening 152a. The middle UBM pads of arms 223 are labeled as UBM pads 140d in FIG. 5c. In one embodiment, the middle UBM pads 140 of arms 223 have stencil openings 152d with a length of 410 μm and a width of 300 μm.

UBM pads 140h, at the end of arms 223, use stencil openings 152h elongated in both length and width, but the width is elongated only to the right and not to the left into the arms. For end UBM pads 140, i.e., those UBM pads that have an immediately adjacent UBM pad on only one side, a length of 410 μm and a width of 305 μm is used in one embodiment.

The UBM pads 140 of line 220, labeled as UBM pads 140f in FIG. 5c, are completely separate UBM pads without an immediately adjacent UBM pad in any direction. UBM pads 140f can use a stencil opening 152f elongated in all four directions, up, down, left, and right. In one embodiment, separated UBM pads 140f use a stencil opening with a length of 405 μm and a width of 310 μm.

FIG. 5d illustrates a detailed view of group 226 formed of rectangle UBM pads 190. UBM pads 190 follow essentially the same general rules as UBM pads 140, but the specific dimensions used are different. UBM pads 190 along the top and bottom edges use stencil openings 192e that are elongated vertically but not horizontally, and only in the direction external to the group. UBM pads 190 along the left and right edges use stencil openings 192c that are elongated horizontally but not vertically, and only in the direction external to the group. UBM pads 190 in the corners use stencil openings 192g elongated both vertically and horizontally, but again only in directions external to the group. Internal UBM pads 190, i.e., those UBM pads that have immediately adjacent UBM pads in all four cardinal directions, use the default stencil opening 192a without any elongation.

Using stencil openings that are larger than the UBM pad being bumped improves solder paste coverage by reducing solder voids and reducing the negative impacts of solder voids that persist. A consistent bump height and a completely covered UBM pad can more reliably be achieved. Packages being formed have less defects, which reduces costs up and down the supply chain. The problem of solder voids is typically worse at the edges of groups of UBM pads, so additional elongation along the edges and in corners of UBM pad groups further alleviates problems that can be particularly bad in those areas.

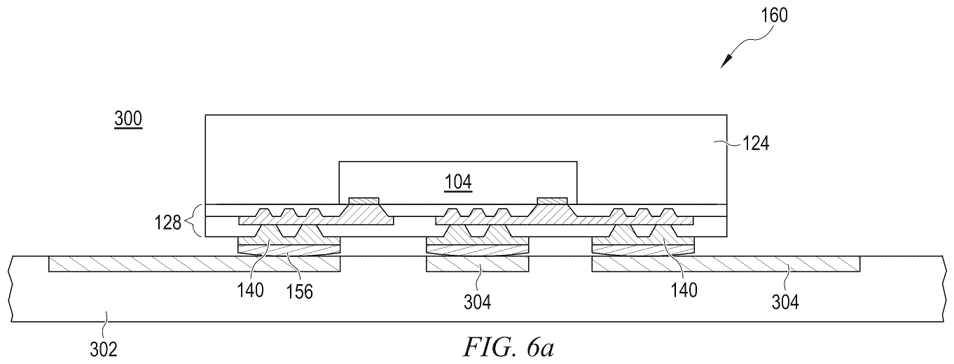

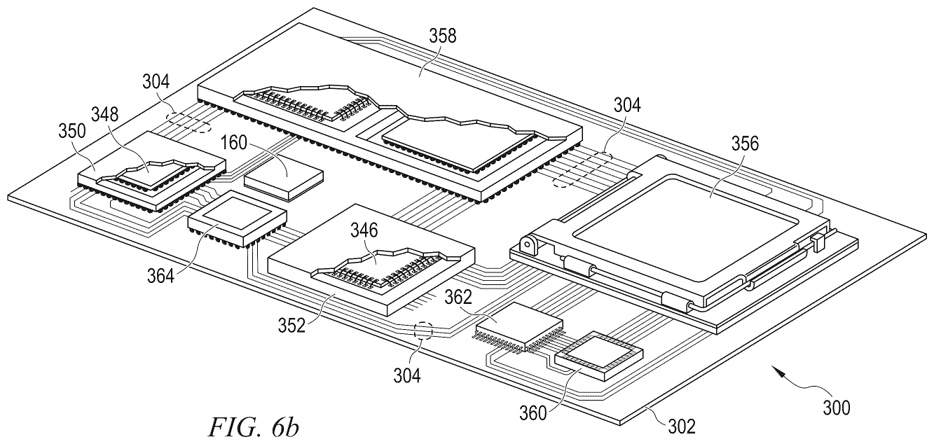

FIGS. 6a and 6b illustrate integrating the above-described semiconductor packages, e.g., FO-WLP 160, into a larger electronic device 300. FIG. 6a illustrates a partial cross-section of FO-WLP 160 mounted onto a printed circuit board (PCB) or other substrate 302 as part of electronic device 300. Bumps 156 are reflowed onto conductive layer 304 of PCB 302 to physically attach and electrically connect FO-WLP 160 to the PCB. In other embodiments, thermocompression or another suitable attachment and connection methods are used. In some embodiments, an adhesive or underfill layer is used between FO-WLP 160 and PCB 302. Semiconductor die 104 is electrically coupled to conductive layer 304 through bumps 156 and interconnect structure 128.

FIG. 6b illustrates electronic device 300 having a chip carrier substrate or PCB 302 with a plurality of semiconductor packages disposed on a surface of PCB 302, including FO-WLP 160. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 6b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims. While a FO-WLP is specifically disclosed, the UBM pad bumping method disclosed above can be used with other types of semiconductor packages as well. For all distance measurements provided herein, the length, width, or other measurement can be any suitable value.

What is claimed:

1. A method of making a semiconductor device, comprising:
providing a semiconductor die;
depositing an encapsulant over the semiconductor die;
forming an interconnect structure over the semiconductor die and encapsulant;
forming a first under-bump metallization (UBM) pad over the interconnect structure, wherein the first UBM pad is non-circular;
disposing a stencil over the first UBM pad, wherein the stencil includes a first opening over the first UBM pad with a footprint of the first opening larger than a footprint of the first UBM pad;
depositing a solder paste in the first opening; and
reflowing the solder paste to form a solder bump on the UBM pad.

2. The method of claim 1, further including forming a group of UBM pads over the interconnect structure, wherein:
the first UBM pad is formed on an edge of the group of UBM pads;
a second UBM pad is formed internal to the group of UBM pads;
the stencil includes a second opening over the second UBM pad; and
the first opening of the stencil is larger than the second opening by being elongated in a direction perpendicular to the edge of the group of UBM pads.

3. The method of claim 1, further including forming a group of UBM pads over the interconnect structure, wherein:
the first UBM pad is formed at a corner of the group of UBM pads;
a second UBM pad is formed internal to the group of UBM pads;
the stencil includes a second opening over the second UBM pad; and
the first opening of the stencil is larger than the second opening by being elongated in both length and width.

4. The method of claim 1, wherein the first UBM pad is oblong or rectangular shaped.

5. The method of claim 1, wherein the first opening of the stencil has a length and width equal to a length and width of the first UBM pad and a corner radius of the first opening is less than a corner radius of the first UBM pad.

6. The method of claim 1, wherein the first opening includes a length or width greater than a parallel dimension of the first UBM pad.

7. A method of making a semiconductor device, comprising:
providing a semiconductor die;
depositing an encapsulant over the semiconductor die;
forming an interconnect structure over the semiconductor die and encapsulant;
forming a first under-bump metallization (UBM) pad over the interconnect structure; and
disposing a stencil over the first UBM pad, wherein the stencil includes a first opening over the first UBM pad with a footprint of the first opening larger than a footprint of the first UBM pad.

8. The method of claim 7, further including forming a group of UBM pads over the interconnect structure, wherein:
the first UBM pad is formed on an edge of the group of UBM pads;
a second UBM pad is formed internal to the group of UBM pads;
the stencil includes a second opening over the second UBM pad; and
the first opening of the stencil is larger than the second opening by being elongated in a direction perpendicular to the edge of the group of UBM pads.

9. The method of claim 7, further including forming a group of UBM pads over the interconnect structure, wherein:
the first UBM pad is formed at a corner of the group of UBM pads;
a second UBM pad is formed internal to the group of UBM pads;
the stencil includes a second opening over the second UBM pad; and
the first opening of the stencil is larger than the second opening by being elongated in both length and width.

10. The method of claim 7, wherein the first UBM pad is oblong or rectangular shaped.

11. The method of claim 7, wherein the first opening of the stencil has a length and width equal to a length and width of the first UBM pad and a corner radius of the first opening is less than a corner radius of the first UBM pad.

12. The method of claim 7, wherein the first opening includes a length or width greater than a parallel dimension of the first UBM pad.

13. The method of claim 7, further including depositing a solder paste in the first opening on the first UBM pad.

14. A method of making a semiconductor device, comprising:
providing a first under-bump metallization (UBM) pad; and
disposing a stencil over the first UBM pad, wherein the stencil includes a first opening over the first UBM pad with a footprint of the first opening larger than a footprint of the first UBM pad.

15. The method of claim 14, further including forming a group of UBM pads, wherein:
the first UBM pad is formed on an edge of the group of UBM pads;
a second UBM pad is formed internal to the group of UBM pads;
the stencil includes a second opening over the second UBM pad; and
the first opening of the stencil is larger than the second opening by being elongated in a direction perpendicular to the edge of the group of UBM pads.

16. The method of claim 14, further including forming a group of UBM pads, wherein:
the first UBM pad is formed at a corner of the group of UBM pads;
a second UBM pad is formed internal to the group of UBM pads;
the stencil includes a second opening over the second UBM pad; and
the first opening of the stencil is larger than the second opening by being elongated in both length and width.

17. The method of claim 14, wherein the first UBM pad is oblong or rectangular shaped.

18. The method of claim 14, wherein the first opening of the stencil has a length and width equal to a length and width of the first UBM pad and a corner radius of the first opening is less than a corner radius of the first UBM pad.

19. The method of claim 14, wherein the first opening includes a length or width greater than a parallel dimension of the first UBM pad.

20. A semiconductor device, comprising:
a first under-bump metallization (UBM) pad; and
a stencil disposed over the first UBM pad, wherein the stencil includes a first opening over the first UBM pad with a footprint of the first opening larger than a footprint of the first UBM pad.

21. The semiconductor device of claim 20, further including a group of UBM pads, wherein:
the first UBM pad is formed on an edge of the group of UBM pads;
a second UBM pad is formed internal to the group of UBM pads;
the stencil includes a second opening over the second UBM pad; and
the first opening of the stencil is larger than the second opening by being elongated in a direction perpendicular to the edge of the group of UBM pads.

22. The semiconductor device of claim 20, further including a group of UBM pads, wherein:
the first UBM pad is formed at a corner of the group of UBM pads;
a second UBM pad is formed internal to the group of UBM pads;
the stencil includes a second opening over the second UBM pad; and
the first opening of the stencil is larger than the second opening by being elongated in both length and width.

23. The semiconductor device of claim 20, wherein the first UBM pad is oblong or rectangular shaped.

24. The semiconductor device of claim 20, wherein the first opening of the stencil has a length and width equal to a length and width of the first UBM pad and a corner radius of the first opening is less than a corner radius of the first UBM pad.

25. The semiconductor device of claim 20, wherein the first opening includes a length or width greater than a parallel dimension of the first UBM pad.
